(19) United States
(12) Patent Application Publication
(10) Pub. No.: US 2013/0228843 A1
(43) Pub. Date: Sep. 5, 2013

(54) NONVOLATILE MEMORY DEVICE AND METHOD OF FABRICATING THE SAME

(71) Applicants: Tai-Soo LIM, Seoul (KR); Kihyun YUN, Seoul (KR); Jeonggil LEE, Hwaseong-si (KR); HyunSeok LIM, Gwangju (KR); HAUK HAN, Hwaseong-si (KR); MYOUNGBUM LEE, Seoul (KR)

(72) Inventors: Tai-Soo LIM, Seoul (KR); Kihyun YUN, Seoul (KR); Jeonggil LEE, Hwaseong-si (KR); HyunSeok LIM, Gwangju (KR); HAUK HAN, Hwaseong-si (KR); MYOUNGBUM LEE, Seoul (KR)

(21) Appl. No.: 13/761,327

(22) Filed: Feb. 7, 2013

(30) Foreign Application Priority Data
Mar. 2, 2012 (KR) 10-2012-0021672

(51) Int. Cl. H01L 29/788; H01L 29/792

(52) U.S. Cl. CPC H01L 29/788; H01L 29/792
USPC 257/315; 257/324

(57) ABSTRACT

A nonvolatile memory device includes a memory gate pattern on a substrate, and a non-memory gate pattern on the substrate, the non-memory gate pattern being spaced apart from the memory gate pattern, wherein the non-memory gate pattern includes an ohmic layer, and the memory gate pattern is provided without an ohmic layer.

### CROSS-REFERENCE TO RELATED APPLICATIONS

This U.S. non-provisional patent application claims priority under 35 U.S.C. §119 to Korean Patent Application No. 10-2012-0021672, filed on Mar. 2, 2012, in the Korean Intellectual Property Office, the entire contents of which are hereby incorporated by reference.

### BACKGROUND

1. Field

Example embodiments of the inventive concept relate to a nonvolatile memory device and a method of fabricating the same.

2. Description of Related Art

A cell array region of a nonvolatile memory device is provided with memory patterns configured to store data and word lines configured to electrically control or operate the memory patterns. In addition, the nonvolatile memory device is further provided with a peripheral circuit controlling the word line. Conventionally, the peripheral circuit may be realized with metal-oxide-semiconductor field-effect transistors (MOSFETs).

As an integration density of the nonvolatile memory device increases, line widths of the word lines are rapidly decreasing. Accordingly, decreasing line or sheet resistance of the word line becomes an important factor in improving operation characteristics of the memory pattern (e.g., writing or reading speed). For example, gate electrodes in the peripheral circuit region are generally configured to be wider and shorter than the word line, so an operation speed of the peripheral circuit transistor may not be greatly affected by line or sheet resistance of the gate electrode.

### SUMMARY

Example embodiments of the inventive concept provide a nonvolatile memory device with a fast operating speed.

Other example embodiments of the inventive concept provide a semiconductor device with a fast operating speed.

Still other example embodiments of the inventive concept provide a method of fabricating a nonvolatile memory device with a fast operating speed.

According to example embodiments of the inventive concepts, a nonvolatile memory device may include a substrate, a memory gate pattern on the substrate, and a non-memory gate pattern on the substrate, the non-memory gate pattern being spaced apart from the memory gate pattern, wherein the non-memory gate pattern includes an ohmic layer, and the memory gate pattern is provided without an ohmic layer.

In example embodiments, the ohmic layer may be a metal silicide layer.

In example embodiments, the memory gate pattern may include a tunnel insulating layer, a data storing pattern, a first blocking insulating layer, and a control gate pattern arranged in order written, and the control gate pattern may be provided without the ohmic layer.

In example embodiments, the data storing pattern may be one of a floating gate pattern or a charge trap layer.

In example embodiments, the nonvolatile memory device may be a NAND FLASH memory device, the control gate pattern serves as a word line of the NAND FLASH memory device, and the non-memory gate pattern serves as at least one of gate patterns of string and ground selection transistors.

In example embodiments, the control gate may include a first lower conductive pattern, a resistor pattern, a first diffusion barrier pattern, and a first upper conductive pattern, which may be sequentially stacked on the substrate, and the resistor pattern has electric resistance higher than the ohmic layer. The resistor pattern may be formed of metal silicon nitrides.

In example embodiments, the non-memory gate pattern may include a second lower conductive pattern, the ohmic layer, a second diffusion barrier pattern, and a second upper conductive pattern, which may be sequentially stacked on the substrate, and the data storing pattern and the second lower conductive pattern may be formed of the same polysilicon layer.

In example embodiments, the memory gate pattern may include a first lower conductive pattern, a first blocking insulating layer, a first intermediate conductive pattern, a first diffusion barrier pattern, and a first upper conductive pattern stacked on the substrate, and the non-memory gate pattern may include a second lower conductive pattern, a second blocking insulating layer, a second intermediate conductive pattern, a second diffusion barrier pattern disposed adjacent to the second lower conductive pattern through the second intermediate conductive pattern and the second blocking insulating layer, a second upper conductive pattern on the second diffusion barrier pattern, and the ohmic layer interposed between the second diffusion barrier pattern and the second lower conductive pattern and between the second diffusion barrier pattern and the second intermediate conductive pattern.

In example embodiments, the ohmic layer covers a sidewall of the second intermediate conductive pattern and exposes a top surface of the second intermediate conductive pattern, the memory gate pattern may further include a first resistor pattern interposed between the first diffusion barrier pattern and the first intermediate conductive pattern, and the non-memory gate pattern may further include a second resistor pattern interposed between the second diffusion barrier pattern and the top surface of the second intermediate conductive pattern.

In example embodiments, the non-memory gate pattern may further include a metal layer interposed between the ohmic layer and the second diffusion barrier pattern.

In example embodiments, the second blocking insulating layer has a sidewall protruding laterally from a sidewall of the second resistor pattern.

In example embodiments, the device may further include an active pillar protruding from the substrate. The memory gate pattern may be disposed adjacent to a sidewall of the active pillar.

In example embodiments, the device may further include a semiconductor pattern provided apart from the substrate in a vertical direction, and an active pillar vertically protruding from the semiconductor pattern. The memory gate pattern may be disposed adjacent to a sidewall of the active pillar, and the non-memory gate pattern may be disposed below the semiconductor pattern.

In example embodiments, the substrate may include a cell array region and a peripheral circuit region, the memory gate pattern may be provided in the cell array region, and the non-memory gate pattern may be provided in the peripheral circuit region.

According to example embodiments of the inventive concepts, a semiconductor device may include a first insulating layer, a first conductive pattern, a second insulating layer, and a second conductive pattern sequentially stacked on substrate, a diffusion barrier pattern penetrating the second conductive pattern and the second blocking insulating layer and being disposed adjacent to the first conductive pattern, an ohmic layer interposed between a sidewall of the second conductive pattern and the diffusion barrier pattern and between the first conductive pattern and the diffusion barrier pattern, and a resistor pattern interposed between a top surface of the second conductive pattern and the diffusion barrier pattern.

In example embodiments, the resistor pattern has electric resistance higher than the ohmic layer. In example embodiments, the resistor pattern may be formed of metal silicon nitrides.

In example embodiments, the second insulating layer has a sidewall protruding laterally from a sidewall of the resistor pattern. The device may further include a metal layer interposed between the ohmic layer and the diffusion barrier pattern.

According to example embodiments of the inventive concepts, a nonvolatile memory device includes a memory gate pattern on a substrate, the memory gate pattern including a gate electrode having no direct contact with an ohmic layer, and a non-memory gate pattern on the substrate, the non-memory gate pattern including an ohmic layer and being spaced apart from the memory gate pattern.

In example embodiments, the gate electrode of the memory gate pattern may include metal, the metal having no direct contact with a metal silicide layer.

In example embodiments, the ohmic layer in the non-memory gate pattern may be a metal silicide layer, the non-memory gate pattern being in a peripheral circuit region.

According to example embodiments of the inventive concepts, a method of fabricating a nonvolatile memory device may include sequentially stacking a first insulating layer, a first conductive layer, a second insulating layer, and a second conductive layer on a substrate including a memory region and a non-memory region, partially removing the second conductive layer and the second insulating layer from the non-memory region to form a butting region exposing the first conductive layer, forming an ohmic layer on at least a sidewall of the second conductive layer and the first conductive layer, which may be exposed in the butting region, sequentially forming a diffusion barrier layer and a third conductive layer on the second conductive layer, and patterning the third conductive layer, the diffusion barrier layer, the second conductive layer, the second insulating layer, the first conductive layer, and the first insulating layer to form a memory gate pattern and a non-memory gate pattern on the memory region and the non-memory region, respectively. The non-memory gate pattern may include a metal silicide layer.

In example embodiments, the ohmic layer extends outward from the butting region to cover a top surface of the second conductive layer, and the method may further include removing the ohmic layer from the top surface of the second conductive layer.

In example embodiments, the method may further include forming a third insulating layer provided on the second conductive layer in at least the memory region, before the forming of the butting region, and removing the third insulating layer, after the forming of the ohmic layer.

In example embodiments, the third insulating layer may be formed on the second conductive layer in both of the non-memory region and the memory region, the third insulating layer may be patterned during the forming of the butting region, and the ohmic layer may be formed on a region excepting a surface of the third insulating layer.

In example embodiments, the forming of the ohmic layer may include forming a metal layer on the third insulating layer and thermally treating the structure provided with the metal layer, the method may further include removing a portion of the metal layer, which may be not transformed into the ohmic layer, from at least the memory region.

In example embodiments, the forming of the diffusion barrier layer may include forming a resistor layer at an interface between the second conductive layer and the diffusion barrier layer.

According to example embodiments of the inventive concepts, a method of fabricating a nonvolatile memory device may include providing a substrate with a cell array region and a peripheral circuit region, forming a memory gate pattern provided without an ohmic layer on the cell array region of the substrate, and forming a non-memory gate pattern provided with an ohmic layer on the peripheral circuit region of the substrate.

### BRIEF DESCRIPTION OF THE DRAWINGS

Features will become apparent to those of ordinary skill in the art by describing in detail exemplary embodiments with reference to the attached drawings, in which:

FIGS. 1A and 1B illustrate sectional views of a nonvolatile memory device according to example embodiments of the inventive concept.

FIG. 2A illustrates a sectional view of a memory device according to example embodiments of the inventive concept.

FIGS. 2B and 2C illustrate enlarged sectional views of portions P1 and P2 of FIG. 2A.

FIGS. 3 through 10 illustrate sectional views of a method of fabricating a nonvolatile memory device according to example embodiments of the inventive concept.

FIGS. 11 through 14 illustrate sectional views of a method of fabricating a nonvolatile memory device according to other example embodiments of the inventive concept.

FIG. 15 illustrates a sectional view of other example of nonvolatile memory devices according to example embodiments of the inventive concept.

FIGS. 16 and 17 illustrate sectional views of a method of fabricating a nonvolatile memory device according to other example embodiments of the inventive concept.

FIG. 18 illustrates a sectional view of nonvolatile memory devices according to other example embodiments of the inventive concept.

FIGS. 19 and 20 illustrate sectional views of a method of fabricating a nonvolatile memory device according to still other example embodiments of the inventive concept.

FIGS. 21 through 23 illustrate sectional views of a method of fabricating a nonvolatile memory device according to still other example embodiments of the inventive concept.

FIG. 24 illustrates a sectional view of nonvolatile memory devices according to example embodiments of the inventive concept.

FIG. 25 illustrates a sectional view of nonvolatile memory devices according to example embodiments of the inventive concept.

FIG. 26 illustrates a sectional view of nonvolatile memory devices according to example embodiments of the inventive concept.

FIG. 27 illustrates a schematic block diagram of a memory system with a vertical semiconductor device according to example embodiments of the inventive concept.

FIG. 28 illustrates a schematic block diagram of a memory card with a vertical semiconductor device according to example embodiments of the inventive concept.

FIG. 29 illustrates a schematic block diagram of an information processing system with a vertical semiconductor device according to example embodiments of the inventive concept.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element (s) or feature (s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

In other words, the figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In certain embodiments, a memory layer to be described in this specification may be used as a gate insulating layer of a transistor. Alternatively, a tunnel insulating layer in the memory layer may be used as the gate insulating layer.

Hereinafter, example embodiments of the inventive concept will be described in detail with reference to the accompanying drawings. In certain embodiments, semiconductor memory devices to be described below may be configured to have a three-dimensional structure.

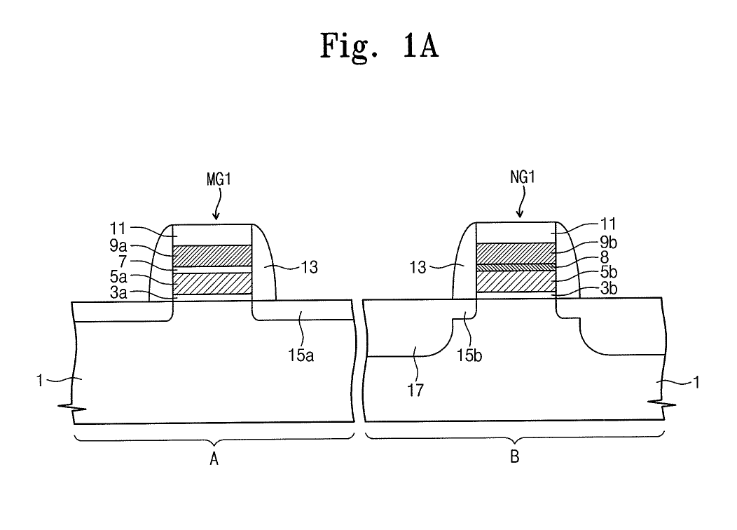

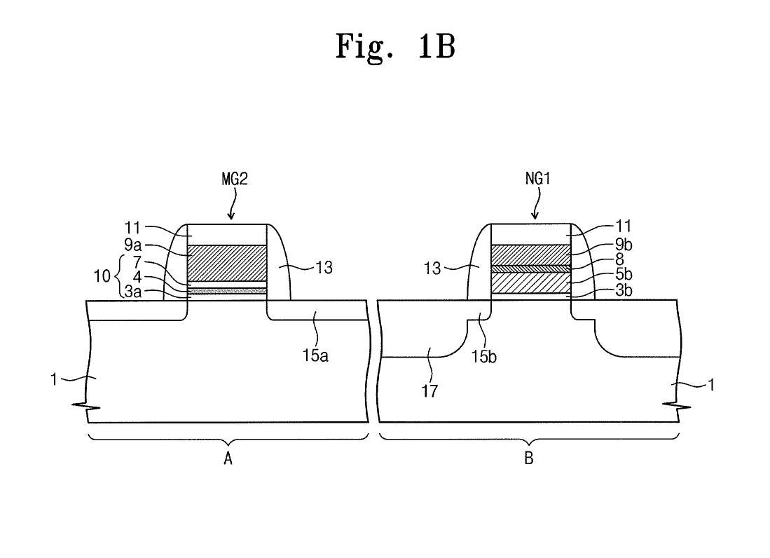

FIGS. 1A and 1B are sectional views of a nonvolatile memory device according to example embodiments of the inventive concept.

Referring to FIG. 1A, in a nonvolatile memory device according to the inventive concept, a memory gate pattern MG1 and a non-memory gate pattern NG1 may be provided on a memory region A and a non-memory region B, respectively, of a substrate 1.

The memory gate pattern MG1 may include a tunnel insulating layer 3a, a floating gate pattern 5a, a blocking insulating layer 7, and a control gate electrode 9a sequentially stacked on the memory region A of the substrate 1. The tunnel insulating layer 3a may be formed of, e.g., a silicon oxide layer. The floating gate pattern 5a may serve as a data storage. The floating gate pattern 5a may include, e.g., impurities, and may be formed of, e.g., a doped polysilicon layer. The blocking insulating layer 7 may include, e.g., at least one of a silicon oxide layer, a multilayer of oxide-nitride-oxide, and a high-k dielectric layer having a dielectric constant higher than the silicon oxide layer. The control gate electrode 9a may be configured not to include an ohmic layer, e.g., may not include a metal silicide layer. The control gate electrode 9a may be a single metal pattern, may include a diffusion barrier pattern and a metal pattern stacked thereon, or may include a stack of a polysilicon pattern, a diffusion barrier pattern, and a metal pattern, which may be sequentially stacked on the blocking insulating layer 7. The diffusion barrier pattern may be a metal nitride layer. The metal pattern may include a metal (e.g., tungsten, copper, or aluminum).

As disused previously, the control gate electrode 9a may not include an ohmic layer. Conventionally, when a metal layer is formed directly on a metal silicide with a crystallized structure, the metal layer may have a reduced grain size. The reduced grain size may leads to an increase in resistivity of the metal layer or the control gate. However, according to example embodiments of the inventive concept, as the control gate electrode 9a may not include the metal silicide layer (an ohmic layer), a grain size of the metal pattern constituting the control gate electrode 9a may be increased. Further, line and sheet resistances of the control gate electrode 9a may be reduced and data transferring speed in the memory region may be increased.

The non-memory gate pattern NG1 may include a gate insulating layer 3b, a first conductive pattern 5b, an ohmic layer 8, and a second conductive pattern 9b sequentially stacked on the non-memory region B of the substrate 1. In example embodiments, the first conductive pattern 5b may be, e.g., a doped polysilicon layer. The ohmic layer 8 may be, e.g., a metal silicide layer. The second conductive pattern 9b may include a diffusion barrier pattern and a metal pattern stacked thereon. Due to the presence of the ohmic layer 8 in the non-memory gate pattern NG1, it is possible to reduce an interfacial resistance between the first conductive pattern 5b and the second conductive pattern 9b. Accordingly, voltage applied to the second conductive pattern 9b can be effectively delivered to the first conductive pattern 5b, and consequently, a channel region can be easily formed in a portion of the substrate 1 under the first conductive pattern 5b. As a result, transistors of the non-memory region B can have an increased signal delivering speed.

Capping patterns 11 and spacers 13 may be provided to cover top and side surfaces, respectively, of the memory gate pattern MG1 and the non-memory gate pattern NG1. The capping pattern 11 and the spacer 13 may be formed of, e.g., a silicon nitride layer.

In the memory region A, a first doped region 15a may be formed in the substrate 1 adjacent to the memory gate pattern MG1. In the non-memory region B, second doped regions 15b and 17 may be formed in the substrate 1 adjacent to the non-memory gate pattern NG1. In example embodiments, the second doped regions 15b and 17 may include a lightly doped region 15b and a highly doped region 17.

Referring to FIG. 1B, in a nonvolatile memory device according to another example, a memory gate pattern MG2 may include the tunnel insulating layer 3a, a charge trap layer 4, the blocking insulating layer 7, and the control gate electrode 9a, which may be sequentially stacked on the substrate 1. The charge trap layer 4 may be, e.g., a silicon nitride layer. The tunnel insulating layer 3a, the charge trap layer 4, and the blocking insulating layer 7 may constitute a first gate insulating layer 10. Hereinafter, the gate insulating layer 3b of the non-memory region B may be referred to as a “second gate insulating layer”. Except for the previously described difference, the memory gate pattern MG2 may be configured to have the same features as that of the memory gate pattern MG21 described previously with reference to FIG. 1A.

The formation of the nonvolatile memory devices of FIGS. 1A and 1B may include forming the memory gate patterns MG1 and MG2 on the memory region A of the substrate 1 and then forming the non-memory gate pattern NG1 on the non-memory region B of the substrate 1. However, example embodiments of the inventive concept may not be limited thereto; for example, the memory gate pattern MG1 and MG2 may be formed after the formation of the non-memory gate pattern NG1 or the memory gate pattern MG1 and MG2 and the non-memory gate pattern NG1 may be simultaneously formed. This will be described in more detail below.

[Nonvolatile Memory Devices—An Example]

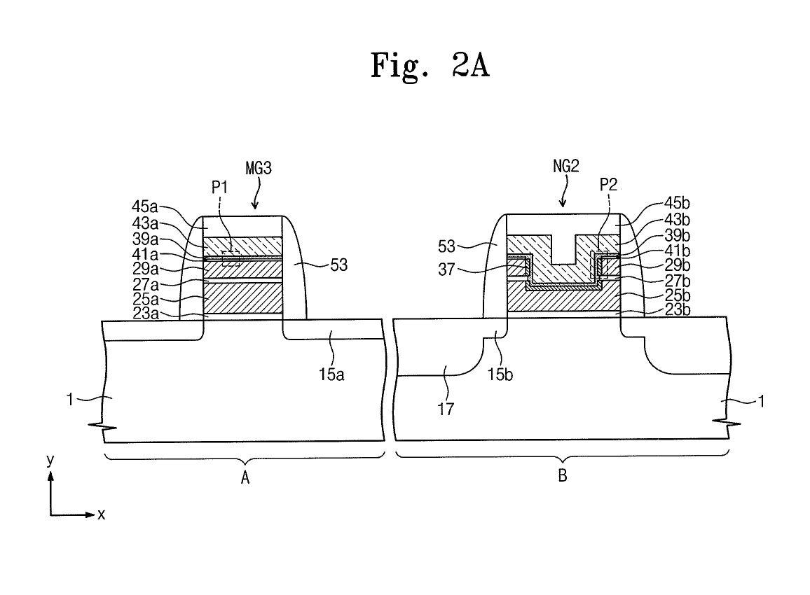

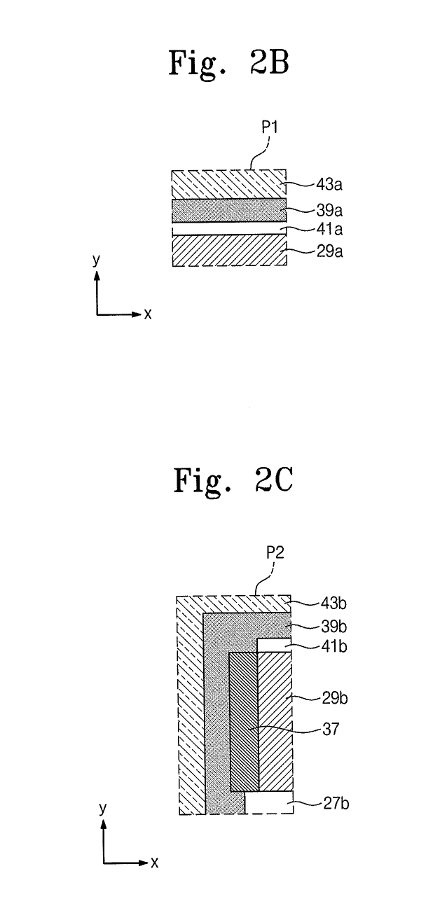

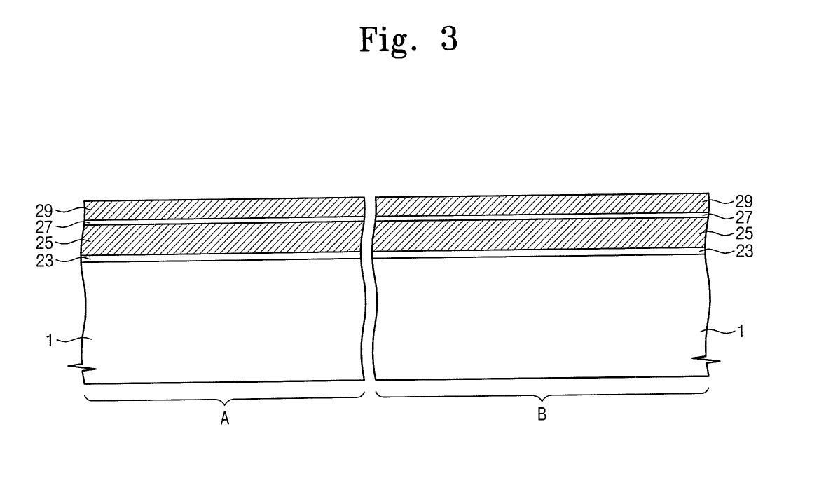

FIG. 2A is a sectional view illustrating a nonvolatile memory device according to other embodiments of the inventive concept. FIGS. 2B and 2C are enlarged sectional views of portions P1 and P2 of FIG. 2A.

Referring to FIGS. 2A and 2B, in a nonvolatile memory device according to the present example, a memory gate pattern MG3 and a non-memory gate pattern NG2 may be provided on the memory region A and the non-memory region B, respectively, of the substrate 1.

The memory gate pattern MG3 may include a tunnel insulating layer 23a, a first lower conductive pattern 25a, a first blocking insulating layer 27a, a first intermediate conductive pattern 29a, a first diffusion barrier pattern 39a, a first upper conductive pattern 43a, and a first capping pattern 45a, which may be sequentially stacked on the substrate 1. A first resistor pattern 41a may be interposed between the first diffusion barrier pattern 39a and the first intermediate conductive pattern 29a. The tunnel insulating layer 23a, the first lower conductive pattern 25a, the first blocking insulating layer 27a, the first intermediate conductive pattern 29a, the first resistor pattern 41a, the first diffusion barrier pattern 39a, and the first upper conductive pattern 43a may have the same or similar width, and moreover, sidewalls thereof may be aligned with each other. For example, the stack of layers and patterns 23a, 25a, 27a, 29a, 41a, 39a, and 43a may be aligned on all sides, e.g., all sidewalls may be aligned to be completely coplanar, to completely overlap each other.

The non-memory gate pattern NG2 may include a gate insulating layer 23b, a second lower conductive pattern 25b, a second blocking insulating layer 27b, a second intermediate conductive pattern 29b, a second resistor pattern 41b, a second diffusion barrier pattern 39b, a second upper conductive pattern 43b, and a second capping pattern 45b, which may be sequentially stacked on the substrate 1. Each of the second lower conductive pattern 25b, the second diffusion barrier pattern 39b, and the second upper conductive pattern 43b may have a width greater than each of the second blocking insulating layer 27b, the second intermediate conductive pattern 29b, and the second resistor pattern 41b, respectively, e.g., along the x-axis. For example, each of the second lower conductive pattern 25b, the second diffusion barrier pattern 39b, and the second upper conductive pattern 43b may extend continuously along an entire width of the gate pattern NG2 structure from one spacer layer 53 to an opposite spacer layer 53 (as seen, e.g., in a cross-sectional view of FIG. 2A), while each of the second blocking insulating layer 27b, the second intermediate conductive pattern 29b, and the second resistor pattern 41b has a width shorter than a distance between two opposite spacer layers 53.

In detail, the second diffusion barrier pattern 39b may cover sidewalls of the second resistor pattern 41b, the second intermediate conductive pattern 29b, and the second blocking insulating layer 27b and a sidewall of the second lower conductive pattern 25b. An ohmic layer 37 may be provided between the second diffusion barrier pattern 39b and the second intermediate conductive pattern 29b, and between the second diffusion barrier pattern 39b and the first lower conductive pattern 25b. The sidewall of the second blocking insulating layer 27b may laterally extend further than that of the second resistor pattern 41b, e.g., along the x-axis as illustrated in FIG. 2C. The first and second resistor patterns 41a and 41b may have lower respective thicknesses along the y-axis than a thickness of the ohmic layer 37 along the x-axis.

The tunnel insulating layer 23a and the gate insulating layer 23b may be formed of the same material (e.g., silicon oxide). The first lower conductive pattern 25a and the second lower conductive pattern 25b may be also formed of the same material (e.g., polysilicon doped with the same dopants). The first and second blocking insulating layers 27a and 27b may be also formed of the same material, e.g., one of silicon oxide, oxide-nitride-oxide (ONO), and high-k dielectrics having dielectric constants higher than silicon oxide. The first and second intermediate conductive patterns 29a and 29b may be also formed of the same material (e.g., polysilicon doped with the same dopants). The first and second diffusion barrier patterns 39a and 39b may be also formed of the same material (e.g., metal nitride). The first and second upper conductive patterns 43a and 43b may include the same metallic material. Each of the first and second resistor patterns 41a and 41b may include at least one material having an electric resistance greater than that of the ohmic layer 37. For example, the ohmic layer 37 may include a metal silicide layer, and the first and second resistor patterns 41a and 41b may include a metal silicon nitride layer.

The non-memory gate pattern NG2 may be wider than the memory gate pattern MG3, e.g., along the x-axis. Sidewalls of the non-memory and memory gate patterns NG2 and MG3 may be covered with the spacer layer 53. The first doped region 15a and the second doped regions 15b and 17 may be provided in portions of the substrate at both sides of the memory gate pattern MG3 and the non-memory gate pattern NG2, respectively.

Although not shown, metal silicide granules may be discontinuously provided on a top surface of the first intermediate conductive pattern 29a adjacent to the first resistor pattern 41a, on a top surface of the second intermediate conductive pattern 29b adjacent to the second resistor pattern 41b, on a side surface of the second intermediate conductive pattern 29b adjacent to the ohmic layer 37, and on a top surface of the second lower conductive pattern 25b. In example embodiments, the metal silicide granules may be scattered to form a non-continuous layer. For example, the metal silicide granules may be spaced apart from each other and each of them may have an island structure. In example embodiments, metallic elements in the resistor patterns 41a and 41b and the ohmic layer 37 may be diffused into and reacted with a polysilicon layer constituting the lower and intermediate conductive patterns 25b, 29a, and 29b, and the metal silicide granules may result from this reaction between the metallic elements and the polysilicon layer. The presence of the metal silicide granules may not affect a grain size or resistance of the upper conductive patterns 43a and 43b.

FIGS. 3 through 10 are sectional views illustrating an example of a method of fabricating a nonvolatile memory device (e.g., of FIG. 2A) according to example embodiments of the inventive concept.

Referring to FIG. 3, a thermal oxide layer 23, a lower conductive layer 25, a blocking insulating layer 27, and an intermediate conductive layer 29 may be sequentially stacked on an entire surface of the substrate 1. The lower conductive layer 25 and the intermediate conductive layer 29 may be formed of doped polysilicon layers, respectively. The blocking insulating layer 27 may be formed of a silicon oxide layer, an ONO layer, and/or high-k dielectrics.

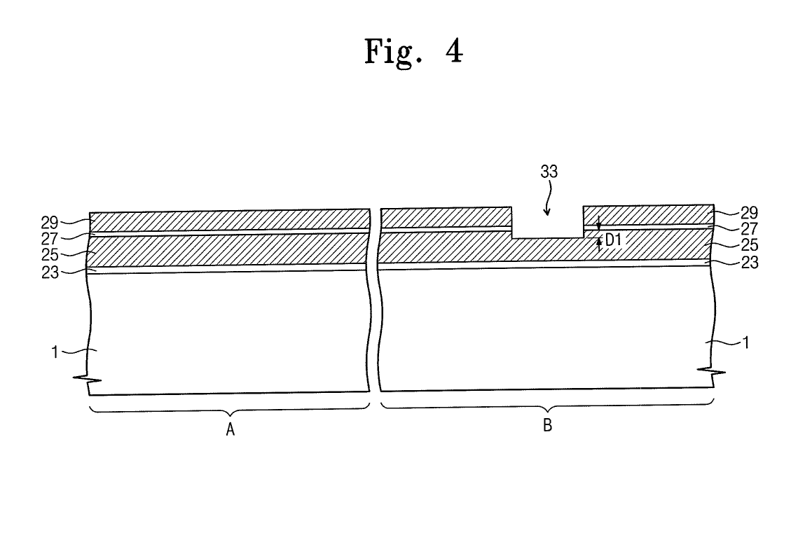

Referring to FIG. 4, the intermediate conductive layer 29 and the blocking insulating layer 27 may be patterned to form a butting region 33 exposing the lower conductive layer 25 in the non-memory region B. A bottom surface of the butting region 33 may be positioned at a level deeper than a bottom surface of the blocking insulating layer 27 by a first depth D1. For example, the first depth D1 may be about 15 nm.

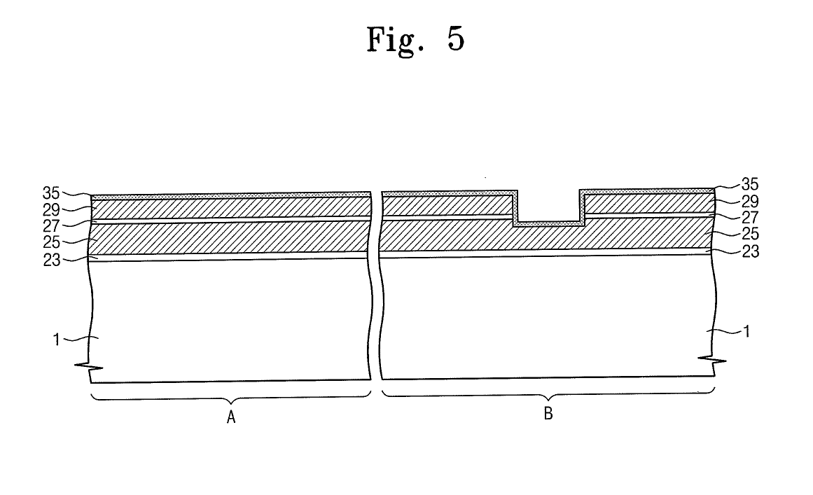

Referring to FIG. 5, a metal layer 35 may be formed to cover conformally the entire surface of the structure formed with the butting region 33. The metal layer 35 may be formed to, e.g., directly, contact the lower conductive layer 25 and the intermediate conductive layer 29. The metal layer 35 may include at least one of, e.g., titanium, tungsten, cobalt, nickel, and tantalum. For example, the metal layer 35 may be a titanium layer, which may be formed by one of, e.g., a chemical vapor deposition (CVD), an atomic layer deposition (ALD), a physical vapor deposition (PVD), or a plasma-enhanced CVD (PECVD) using a gas containing, e.g., titanium tetrachloride (TiCl₄) and hydrogen (H₂).

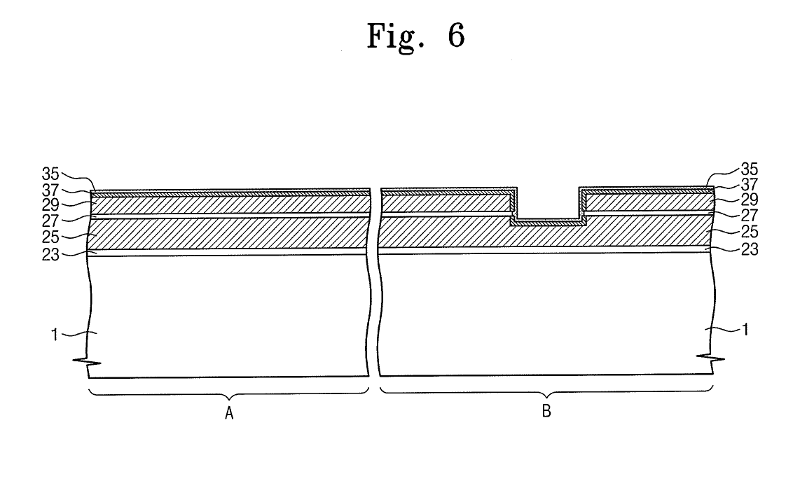

Referring to FIG. 6, after the formation of the metal layer 35, a thermal treatment process may be performed to react the metal layer 35 with the lower and intermediate conductive layers 25 and 29 and form the ohmic layer 37 at an interface therebetween. In example embodiments, the thermal treatment process may be performed at a temperature of about 500-700° C. For example, when the lower and intermediate conductive layers 25 and 29 are formed of polysilicon, the metal in the metal layer 35 reacts with the polysilicon in the lower and intermediate conductive layers 25 and 29 to form an ohmic layer 37 of metal silicide. For example, the ohmic layer 37 may include at least one of titanium silicide, tungsten silicide, cobalt silicide, nickel silicide, and tantalum silicide. In example embodiments, the ohmic layer 37 may be formed in both of the memory region A and the non-memory region B.

According to the embodiments described with reference to FIGS. 5 and 6, the ohmic layer 37 may be formed through two process steps, but example embodiments of the inventive concepts are not limited thereto. For example, the ohmic layer 37 may be formed at the interface between the metal layer 35 and the lower and intermediate conductive layers 25 and 29 during the process of depositing the metal layer 35.

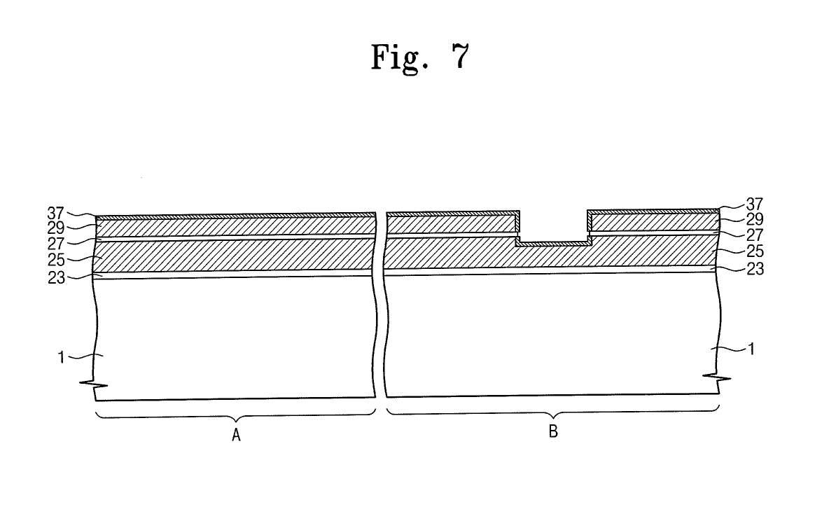

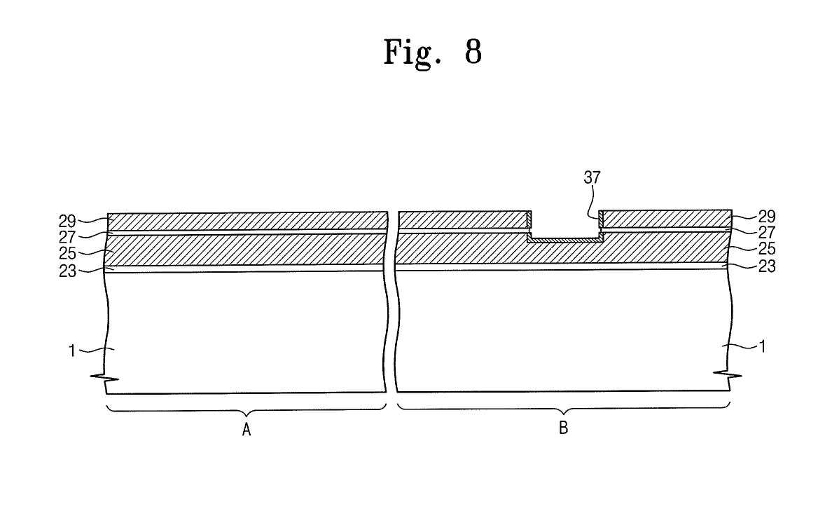

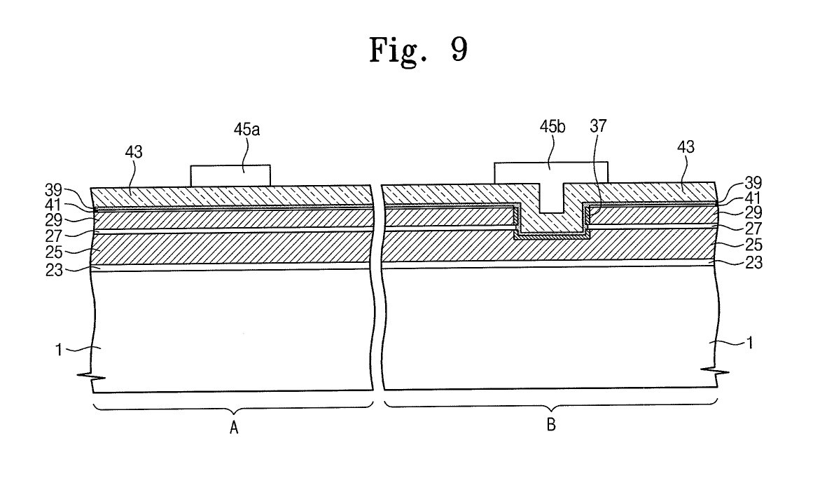

Referring to FIG. 7, an unreacted portion of the metal layer 35, i.e., a portion of the metal layer 35 that is not transformed into the ohmic layer 37, may be selectively removed to expose the ohmic layer 37. The removal of the remaining portion of the metal layer 35 may be performed using, e.g., a selective isotropic etching technique. Next, referring to FIG. 8, after the removal of the remaining portion of the metal layer 35, the butting region 33 may be filled with a sacrificial layer (not shown), and then a planarization process (e.g., chemical mechanical polishing (CMP)) may be performed to remove the ohmic layer 37 from a top surface of the intermediate conductive layer 29. Accordingly, the intermediate conductive layer 29 may have an exposed top surface, and the ohmic layer 37 may remain only in the butting region 33 and cover a side surface of the intermediate conductive layer 29 and a top surface of the lower conductive layer 25 inside the butting region 33. The sacrificial layer may be removed after the planarization process.

Referring to FIG. 9, a diffusion barrier layer 39 may be formed to cover conformally the entire surface of the structure, in which the sacrificial layer has been removed. In example embodiments, the diffusion barrier layer 39 may be formed by depositing a metal layer and then thermally treating the resultant structure under an ammonia gas (NH₃) to form a metal nitride layer. Alternatively, the diffusion barrier layer 39 may be formed by depositing a metal nitride layer. For example, the diffusion barrier layer 39 may be at least one of a titanium nitride layer, a tungsten nitride layer, a cobalt nitride layer, a nickel nitride layer, or a tantalum nitride layer. During the formation of the diffusion barrier layer 39 directly on the intermediate conductive layer 29, a reaction between the diffusion barrier layer 39 and the intermediate conductive layer 29 may form a resistor layer 41 may be formed at an interface between the diffusion barrier layer 39 and the intermediate conductive layer 29. The resistor layer 41 may be formed of a material having electric resistance higher than the ohmic layer 37. The resistor layer 41 may be thinner than the ohmic layer 37. For example, if the diffusion barrier layer 39 is formed of a metal nitride layer and the intermediate conductive layer 29 is formed of a polysilicon layer, the resistor layer 41 may be a metal silicon nitride layer formed from a reaction between the metal nitride layer and the polysilicon.

After the formation of the diffusion barrier layer 39, an upper conductive layer 43 may be formed on the diffusion barrier layer 39. The upper conductive layer 43 may be a metal layer and, for example, may be formed of at least one of tungsten, copper, or aluminum. The first capping pattern 45a and the second capping pattern 45b may be formed in the memory region A and the non-memory region B, respectively, to partially cover a top surface of the upper conductive layer 43.

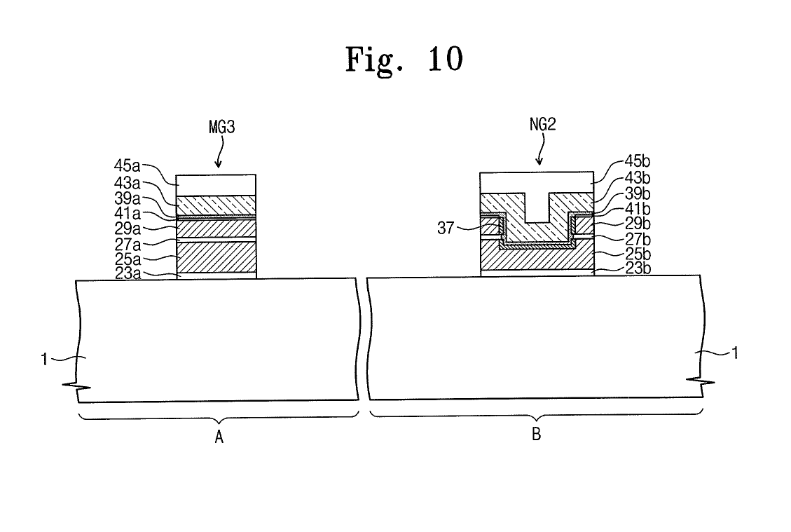

Referring to FIG. 10, a patterning process, in which the first and second capping patterns 45a and 45b are used as an etch mask, may be performed to pattern the underlying layers. As a result, on the memory region A, the memory gate pattern MG3 may be formed to include the tunnel insulating layer 23a, the first lower conductive pattern 25a, the first blocking insulating layer 27a, the first intermediate conductive pattern 29a, the first resistor pattern 41a, the first diffusion barrier pattern 39a, the first upper conductive pattern 43a, and the first capping pattern 45a sequentially stacked on the substrate 1. On the non-memory region B, the non-memory gate pattern NG2 may be formed to include the gate insulating layer 23b, the second lower conductive pattern 25b, the second blocking insulating layer 27b, the second intermediate conductive pattern 29b, the second resistor pattern 41b, the second diffusion barrier pattern 39b, the second upper conductive pattern 43b, the second capping pattern 45b, and the ohmic layer 37. Thereafter, as shown in FIG. 2A, the spacer 53 may be formed to cover the sidewalls of the memory gate pattern MG3 and the non-memory gate pattern NG2, and the doped regions 15a, 15b, and 17 may be formed in the substrate 1.

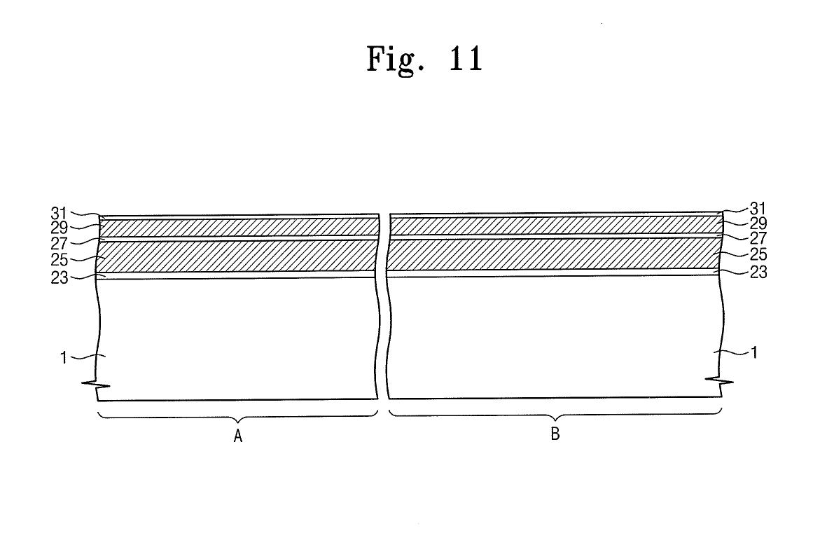

FIGS. 11 through 14 are sectional views illustrating another example of a method of fabricating the nonvolatile memory device (of FIG. 2A) according to example embodiments of the inventive concept.

Referring to FIG. 11, the thermal oxide layer 23, the lower conductive layer 25, the blocking insulating layer 27, the intermediate conductive layer 29, and a protection insulating layer 31 may be sequentially stacked on the substrate 1. The lower conductive layer 25 and the intermediate conductive layer 29 may be formed of doped polysilicon layers, respectively. The blocking insulating layer 27 may be formed of one of a silicon oxide layer, an ONO layer, and/or high-k dielectrics. The protection insulating layer 31 may be formed of a silicon oxide layer, a silicon nitride layer, and/or a silicon oxynitride layer.

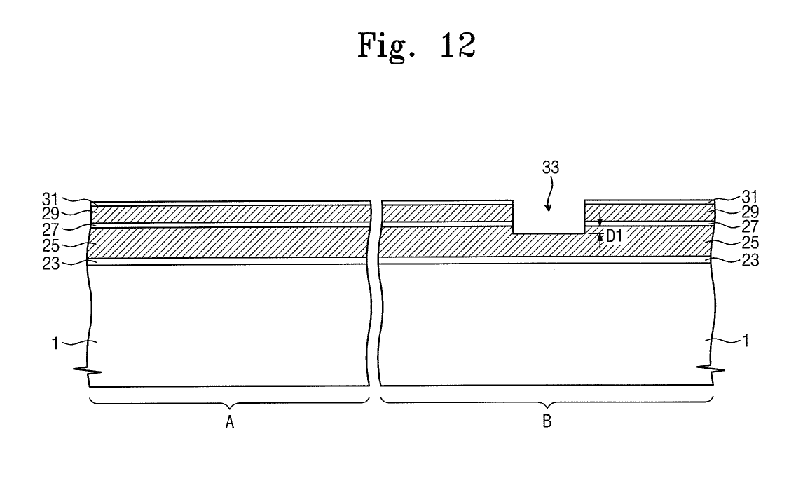

Referring to FIG. 12, the protection insulating layer 31, the intermediate conductive layer 29, and the blocking insulating layer 27 may be patterned to form the butting region 33 exposing the lower conductive layer 25 in the non-memory region B. A bottom surface of the butting region 33 may be positioned at a level deeper than a bottom surface of the blocking insulating layer 27 by the first depth D1. For example, the first depth D1 may be about 15 nm.

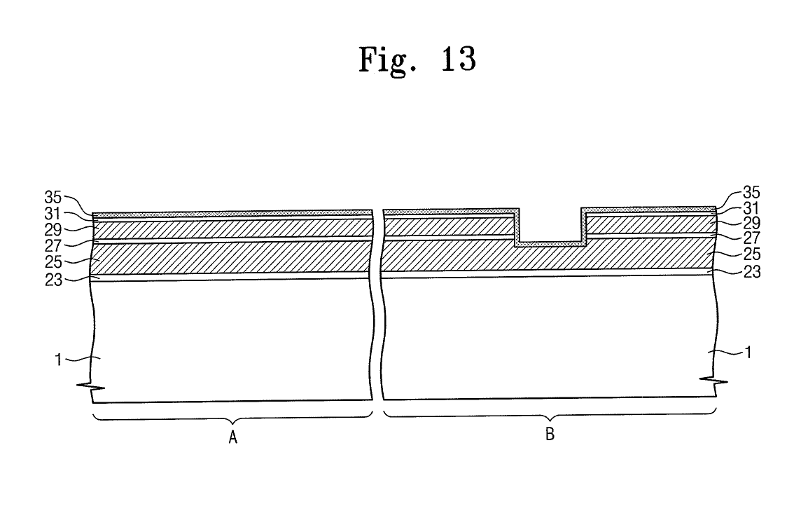

Referring to FIG. 13, the metal layer 35 may be formed to cover conformally the entire surface of the structure formed with the butting region 33. The metal layer 35 may be formed to, e.g., directly, contact the protection insulating layer 31, the lower conductive layer 25, and the intermediate conductive layer 29. The metal layer 35 may include at least one of, e.g., titanium, tungsten, cobalt, nickel, and tantalum. For example, the metal layer 35 may be, e.g., a titanium layer formed by one of a chemical vapor deposition (CVD), an atomic layer deposition (ALD), a physical vapor deposition (PVD), or a plasma-enhanced CVD (PECVD) using a gas containing titanium tetrachloride (TiCl₄) and hydrogen (H₂).

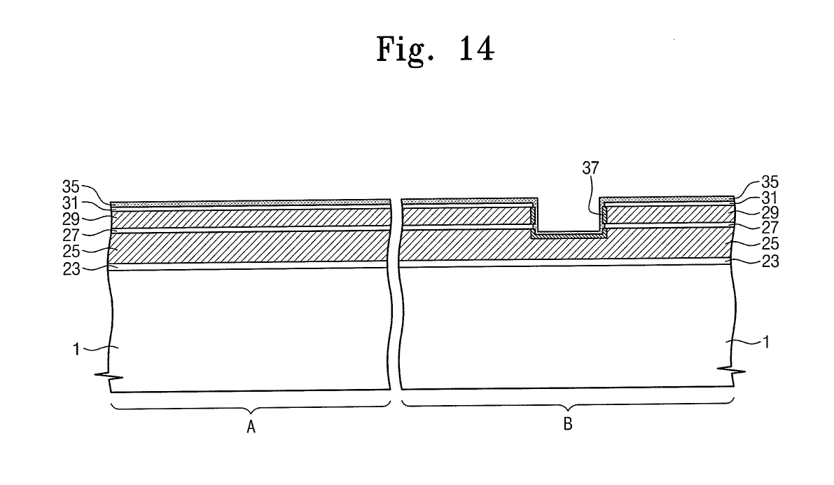

Referring to FIG. 14, after the formation of the metal layer 35, a thermal treatment process may be performed to react the metal layer 35 with the lower and intermediate conductive layers 25 and 29 in the butting region 33 and form the ohmic layer 37 at an interface therebetween. In example embodiments, the ohmic layer 37 may not be formed on the protection insulating layer 31. As a result, a portion of the metal layer 35 may remain on the protection insulating layer 31.

Referring back to FIG. 8, after the removal of the metal layer 35, a planarization process (e.g., chemical mechanical polishing (CMP)) may be performed to remove the protection insulating layer 31 from the intermediate conductive layer 29 and to expose a top surface of the intermediate conductive layer 29. The ohmic layer 37 remains only in the butting region 33. Subsequent process may be performed in the same way as previously described with reference to FIGS. 9 and 10, to form the nonvolatile memory device of FIG. 2A.

[Nonvolatile Memory Devices—Other Example]

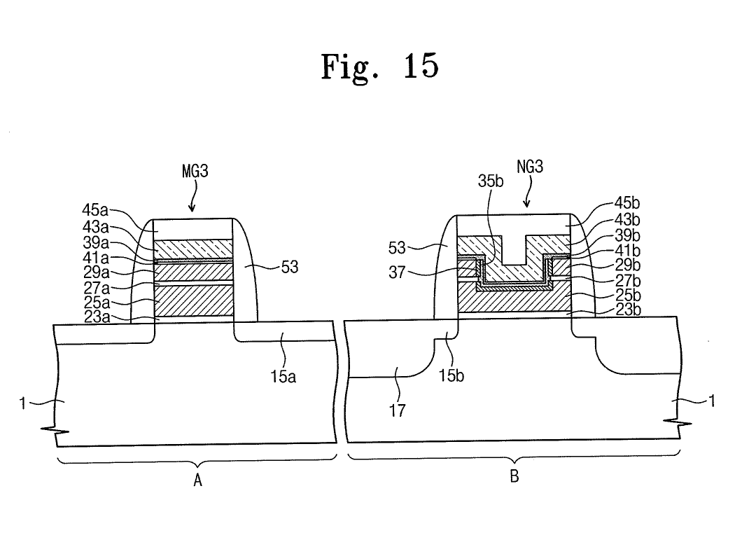

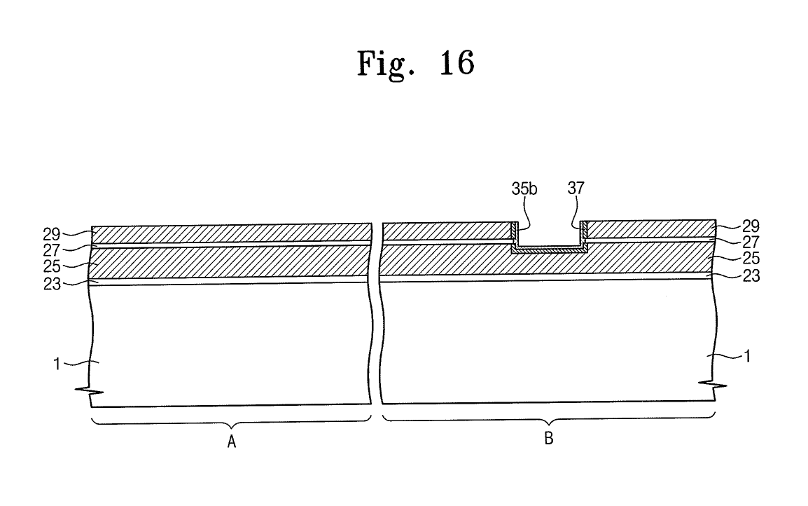

FIG. 15 is a sectional view illustrating another example of a nonvolatile memory device according to example embodiments of the inventive concept.

Referring to FIG. 15, a non-memory gate pattern NG3 according to the present embodiment may further include a metal pattern 35b interposed between the ohmic layer 37 and the second diffusion barrier pattern 39b. Except for the previously-described difference, the non-memory gate pattern NG3 may be configured to have the same features as that of the example previously described with reference to FIG. 2A.

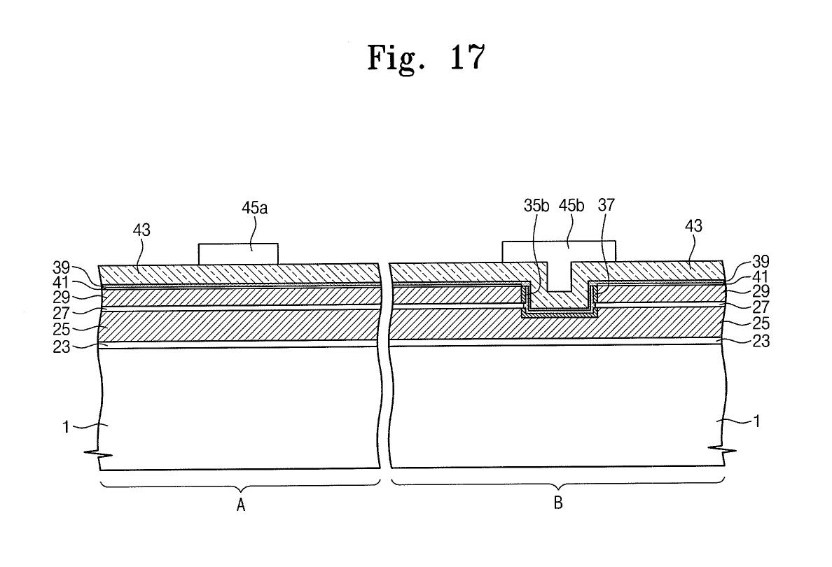

Hereinafter, a process of fabricating the semiconductor device of FIG. 15 will be described with reference to FIGS. 16 and 17.

A planarization process (e.g., CMP) may be performed on the structure of FIG. 6 to remove the ohmic layer 37 and the metal layer 35 from the top surface of the intermediate conductive layer 29, as shown in FIG. 16. As the result of the planarization process, the top surface of the intermediate conductive layer 29 may be exposed and the ohmic layer 37 and the metal pattern 35b may remain in the butting region 33.

Alternatively, a planarization process (e.g., CMP) may be performed on the structure of FIG. 14 to remove the protection insulating layer 31 and the metal layer 35 from the top surface of the intermediate conductive layer 29, as shown in FIG. 16. As the result of the planarization process, the top surface of the intermediate conductive layer 29 may be exposed and the ohmic layer 37 and the metal pattern 35b may remain in the butting region 33.

Referring to FIG. 17, the diffusion barrier layer 39 and the upper conductive layer 43 may be sequentially formed on the substrate 1. Thereafter, a patterning process, in which the first and second capping patterns 45a and 45b are used as an etch mask, may be performed to pattern the underlying layers. Subsequent processes may be performed in the same way as in the previously described processes with reference to FIGS. 9 and 10, to form the nonvolatile memory device of FIG. 2A.

[Nonvolatile Memory Devices—Still Other Example]

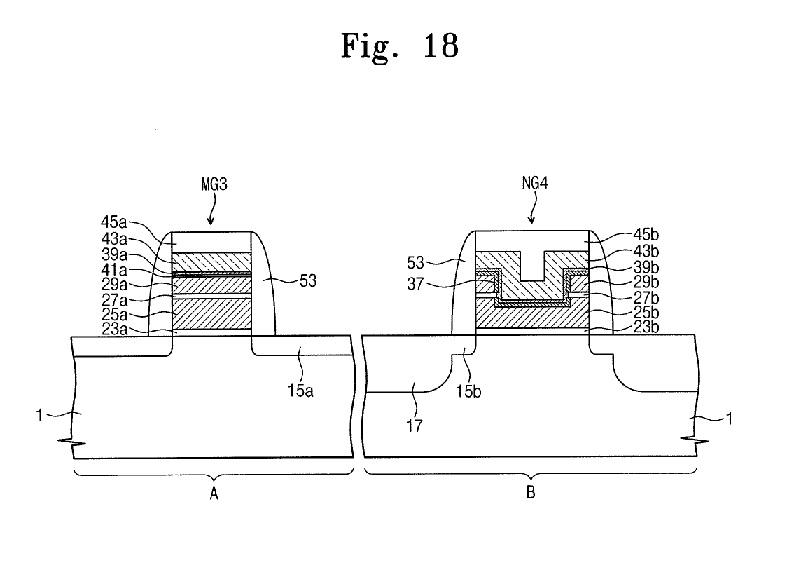

FIG. 18 is a sectional view illustrating still another example of a nonvolatile memory device according to example embodiments of the inventive concept.

Referring to FIG. 18, a non-memory gate pattern NG4 according to the present embodiment may be configured not to include the second resistor pattern 41b of FIG. 2A or 1. In this case, for example, the ohmic layer 37 may be formed to extend, e.g., continuously, between the top surface of the second intermediate conductive pattern 29b and the second diffusion barrier pattern 39b. Except for the previously-described difference, the nonvolatile memory device may be configured to have the same or similar features as that of the example previously described with reference to FIGS. 2A through 2C.

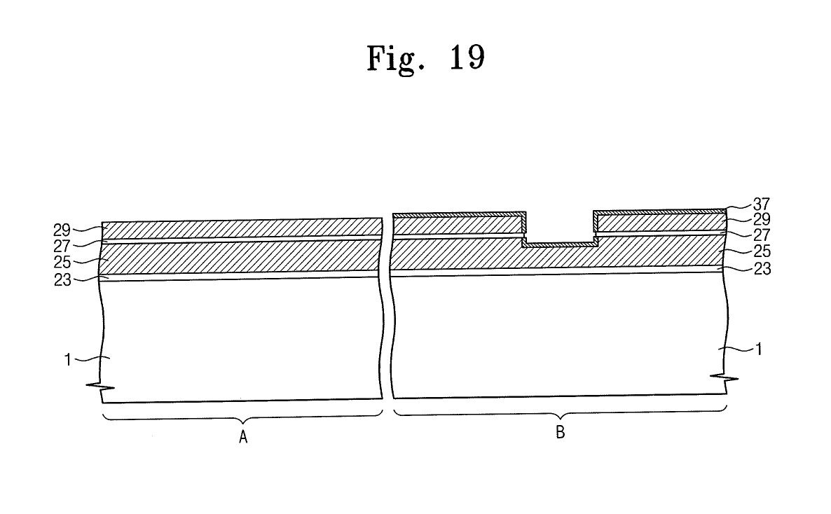

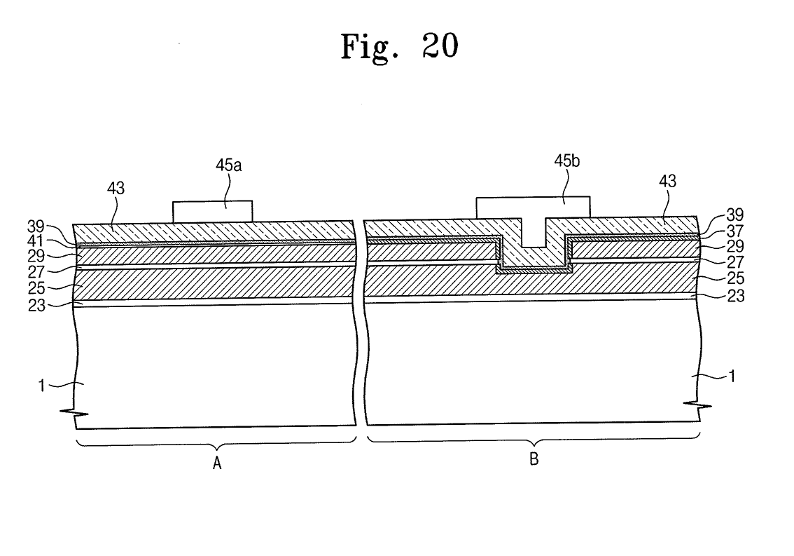

FIGS. 19 and 20 are sectional views illustrating an example of a method of fabricating a nonvolatile memory device (e.g., of FIG. 18) according to still other example embodiments of the inventive concept.

Referring to FIGS. 19 and 20, an etching process may be performed on the structure of FIG. 7 to remove the ohmic layer 37 from the top surface of the intermediate conductive layer 29 of the memory region A and expose the top surface of the intermediate conductive layer 29. Thereafter, the diffusion barrier layer 39 and the upper conductive layer 43 may be sequentially formed on the resultant structure. In example embodiments, the resistor layer 41 may be formed between the intermediate conductive layer 29 and the diffusion barrier layer 39, in the memory region A, but not in the non-memory region B. Thereafter, the process previously described with reference to FIG. 2A may be further performed.

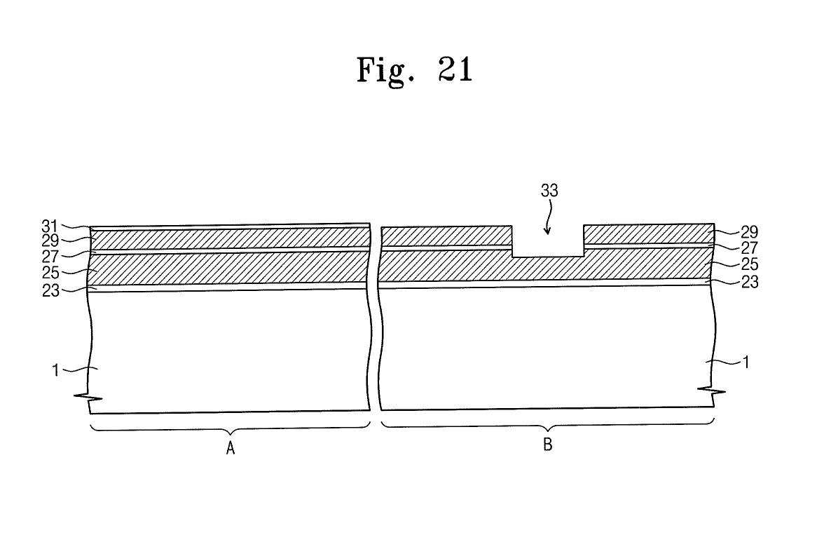

FIGS. 21 through 23 are sectional views illustrating other example of a method of fabricating the nonvolatile memory device (e.g., of FIG. 18) according to still other example embodiments of the inventive concept.

Referring to FIG. 21, the protection insulating layer 31 may be removed from the non-memory region B of the structure of FIG. 11. Accordingly, the top surface of the intermediate conductive layer 29 in the memory region A may be covered with the protection insulating layer 31 and the top surface of the intermediate conductive layer 29 in the non-memory region B may be exposed. Furthermore, the intermediate conductive layer 29 and the blocking insulating layer 27 may be partially removed from the non-memory region B to form the butting region 33.

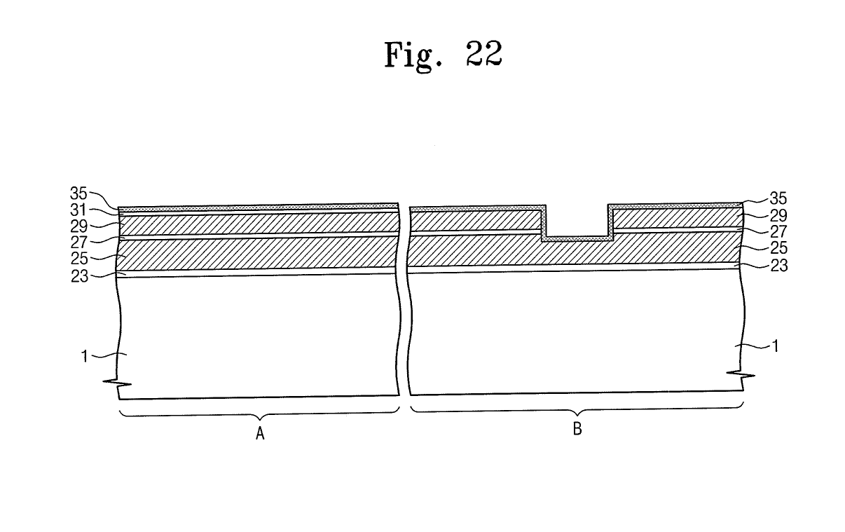

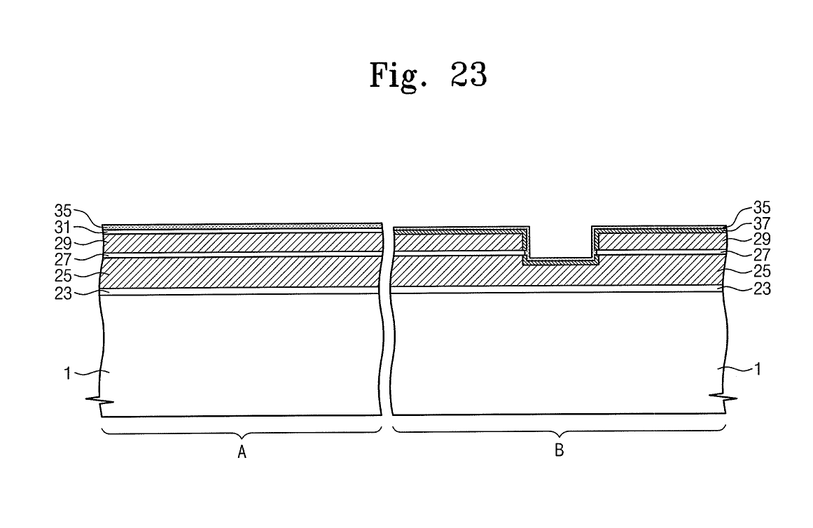

Referring to FIGS. 22 and 23, the metal layer 35 may be conformally formed on the structure formed with the butting region 33, and a thermal treatment process may be performed to form the ohmic layer 37. In example embodiments, the protection insulating layer 31 may prevent the ohmic layer 37 from being formed on the memory region A, but the ohmic layer 37 may be formed on the non-memory region B to cover exposed surfaces of the intermediate conductive layer 29 and the lower conductive layer 25. Subsequently, as described in the embodiments previously described with reference to FIGS. 3 through 14, the metal layer 35 and the protection insulating layer 31 may be removed, and thereafter, the diffusion barrier layer 39 and the upper conductive layer 43 may be formed and patterned.

The non-memory gate patterns NG1, NG2, NG3, and NG4 may be used for gate patterns in transistors constituting various logic or peripheral circuits. For example, gate patterns of transistors constituting a complementary metal-oxide-semiconductor (CMOS) inverter may be realized using one of the non-memory gate patterns NG1, NG2, NG3, and NG4. In the case in which the CMOS inverter is realized using one of the non-memory gate patterns NG1, NG2, NG3, and NG4, an operation speed thereof can be increased by about 70%. This means that it is possible to reduce a propagation delay in CMOS circuits.

[Nonvolatile Memory Devices—Yet Other Example]

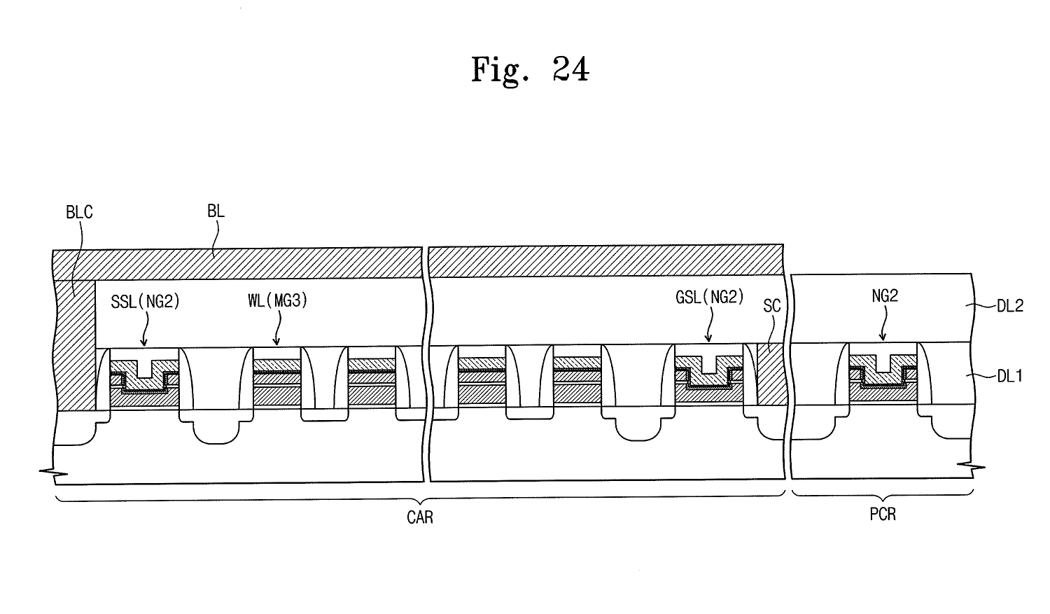

FIG. 24 is a sectional view illustrating yet another example of a nonvolatile memory device according to example embodiments of the inventive concept.

Referring to FIG. 24, a nonvolatile memory device according to the present embodiment may be a NAND FLASH memory device. The nonvolatile memory device may include the substrate 1 with a cell array region CAR and a peripheral circuit region PCR. A ground selection line GSL, a string selection line SSL parallel to the ground selection line GSL, and a plurality of word lines WL interposed parallel to each other between the ground selection line GSL and the string selection line SSL may be provided on the cell array region CAR. The lines GSL, SSL, and WL may extend along a direction and may be spaced apart from and parallel to each other. The ground selection line GSL, the string selection line SSL, and the word lines WL may constitute a single cell string. The cell array region CAR may include a plurality of the cell strings arranged in a symmetric and repeated manner. The word line WL may be configured to have the same structure as the memory gate pattern MG3 described with reference to FIG. 2A. For example, the ground selection line GSL and the string selection line SSL may have the same structure as the non-memory gate pattern NG2 described with reference to FIG. 2A.

Alternatively or additionally, the ground selection line GSL and the string selection line SSL may have the same structure as one of the non-memory gate patterns NG3 and NG4 described with reference to FIGS. 15 and 18. Alternatively or additionally, the word line WL may have the same structure as one of the memory gate patterns MG1 and MG2 described with reference to FIGS. 1A and 1B. Alternatively or additionally, the ground selection line GSL and the string selection line SSL may have the same structure as the non-memory gate pattern NG1 described with reference to FIGS. 1A and 1B. The peripheral circuit region PCR may be provided with the non-memory gate patterns NG2. The doped regions 15a, 15b, and 17 may be provided in the substrate 1 adjacent to the gate patterns NG2 and MG3. Gaps between the gate patterns NG2 and MG3 may be filled with a first interlayer insulating layer DL 1. A common source line SC may be provided on the doped region 15b and 17 adjacent to the ground selection line GSL. A bit line contact BLC may be provided on the doped region 15b and 17 adjacent to the string selection line SSL. A second interlayer insulating layer aDL2 may be provided on the first interlayer insulating layer DL1 and a bit line BL may be provided thereon to be electrically connected to the bit line contact BLC. The bit line BL may extend along a direction crossing the word line WL.

The first resistor pattern 41a in the word line WL may be a factor increasing an interfacial resistance between the first upper conductive pattern 43a and the intermediate conductive pattern 29a. However, during an operation of the device, the word line WL may be applied with a voltage being sufficiently high enough to neglect such an increase in interfacial resistance, and thus, an operation speed of the word line WL may not be substantially affected by the increase in the interfacial resistance. One of the fabricating methods described in the above embodiments may be identically or similarly used to form the nonvolatile memory device of FIG. 24.

[Nonvolatile Memory Devices—Even Other Example]

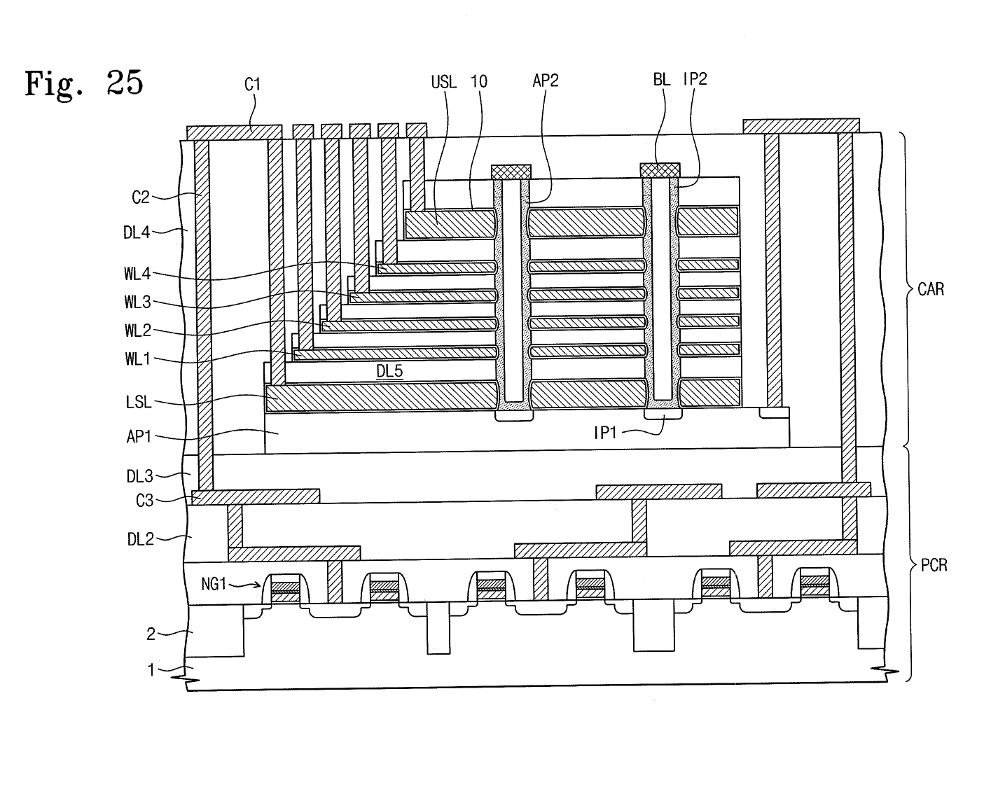

FIG. 25 is a sectional view illustrating even another example of a nonvolatile memory device according to example embodiments of the inventive concept.

Referring to FIG. 25, a nonvolatile memory device according to the present embodiment may be a vertical nonvolatile memory device. For example, in the nonvolatile memory device, the peripheral circuit region PCR may be disposed under the cell array region CAR, e.g., the peripheral circuit region PCR and the cell array region CAR may be sequentially stacked on the substrate 1. The peripheral circuit region PCR may include the substrate 1 and the non-memory gate patterns NG1, which may be formed on an active region defined by a device isolation layer 2. In example embodiments, the non-memory gate patterns NG1 may include the ohmic layer 37, as described with reference to FIGS. 1A and 1B. In addition, the peripheral circuit region PCR may include first to third interlayer insulating layers DL1, DL2, and DL3 and interconnection lines C3.

A semiconductor pattern AP1 may be provided on the peripheral circuit region PCR (e.g., on the third interlayer insulating layer DL3). A plurality of active pillars AP2 may protrude from the semiconductor pattern API. A lower selection line LSL, word lines WL1, WL2, WL3, and WL4, and an upper selection line USL may be sequentially stacked to face sidewalls of the active pillars AP2. The lines LSL, WL1, WL2, WL3, WL4, and USL may extend along a direction parallel to a top surface of the semiconductor pattern AP1 to face a plurality of the active pillars AP2 adjacent to each other. On a specific plane parallel to the top surface of the semiconductor pattern AP1, the lines LSL, WL1, WL2, WL3, WL4, and USL may be spaced apart from each other along a vertical direction and may be parallel to each other. In example embodiments, the lines LSL, WL1, WL2, WL3, WL4, and USL may be formed of a substantially same material. For example, the lines LSL, WL1, WL2, WL3, WL4, and USL may be formed of at least one of a doped polysilicon layer or a metal layer. In example embodiments, the lines LSL, WL1, WL2, WL3, WL4, and USL may be formed not to have the ohmic layer, e.g., not to include a metal silicide layer.

The lines LSL, WL1, WL2, WL3, WL4, and USL may be vertically spaced apart from each other, and a gate interlayer insulating layer DL5 may be interposed between every two adjacent ones of the lines LSL, WL1, WL2, WL3, WL4, and USL. In addition, a gate insulating layer 10 may be interposed between the active pillar AP2 adjacent thereto and each of the lines LSL, WL1, WL2, WL3, WL4, and USL. The gate insulating layer 10 may include a tunnel insulating layer, a data storing pattern, and a blocking insulating layer, as described with reference to FIG. 1B. In example embodiments, the gate insulating layer 10 may extend to be interposed between each of the lines LSL, WL1, WL2, WL3, WL4, and USL and a corresponding gate interlayer insulating layers DL5. A first doped region IP1 may be provided in the semiconductor pattern AP1 below the active pillar AP2, and a second doped region IP2 may be provided in an upper end portion of the active pillar AP2. The lines LSL, WL1, WL2, WL3, WL4, and USL may be formed to have end portions constituting a terraced structure. In example embodiments, bit lines BL may be provided over the active pillar AP2 to cross the lines LSL, WL1, WL2, WL3, WL4, and USL. A structure including the lines LSL, WL1, WL2, WL3, WL4, USL, and BL may be covered with a fourth interlayer insulating layer DL4. The lines LSL, WL1, WL2, WL3, WL4, and USL may be electrically connected to, e.g., the interconnection lines C3 of the peripheral circuit region PCR via upper interconnection lines C1 and upper contact plugs C2.

The nonvolatile memory device of FIG. 25 may be formed by forming the peripheral circuit region PCR with the non-memory gate pattern NG1 and then the cell array region CAR with the lines LSL, WL1, WL2, WL3, WL4, and USL thereon. A process of forming the cell array region CAR in a three-dimensional structure was disclosed in U.S. patent application Ser. No. 12/968,389, the contents of which are herein incorporated by reference in their entirety, and thus, for convenience in description, this process may be omitted below.

[Nonvolatile Memory Devices—Further Example]

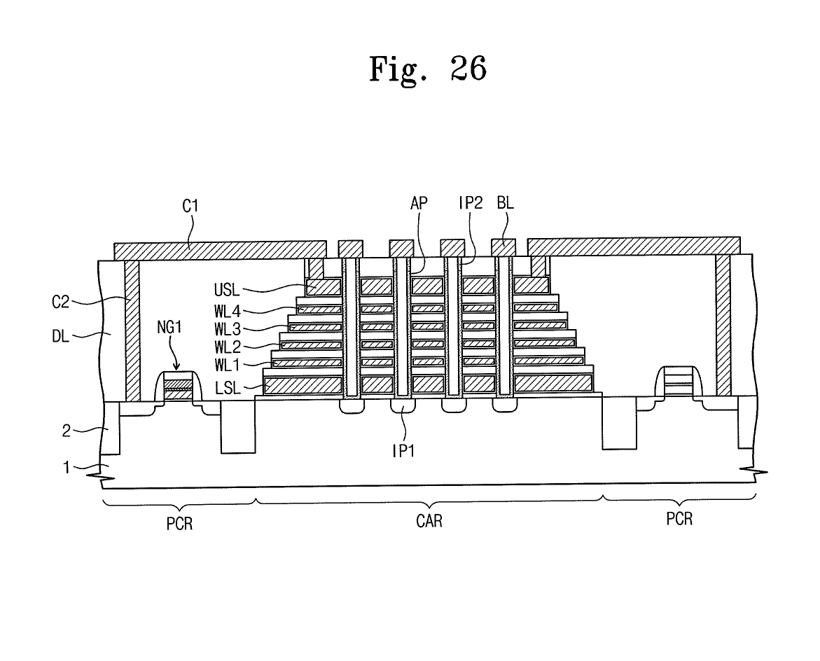

FIG. 26 is a sectional view illustrating a further example of a nonvolatile memory device according to example embodiments of the inventive concept.

Referring to FIG. 26, a nonvolatile memory device according to the present embodiment may be a vertical nonvolatile memory device as in the previous embodiment described with reference to FIG. 25. However, in the nonvolatile memory device, the peripheral circuit region PCR may be disposed on the same plane as the cell array region CAR, such that the peripheral circuit region PCR may be disposed adjacent to or surround the cell array region CAR. Except for the previously-described difference, the nonvolatile memory device may be configured to have the same or similar features as that of the example previously described with reference to FIG. 25.

The nonvolatile memory device of FIG. 26 may be formed by forming the cell array region CAR and thereafter forming the peripheral circuit region PCR. A process of forming the cell array region CAR in a three-dimensional structure was disclosed in U.S. patent application Ser. No. 13/014,188, the contents of which are herein incorporated by reference in their entirety, and thus, for convenience in description, this process may be omitted below.

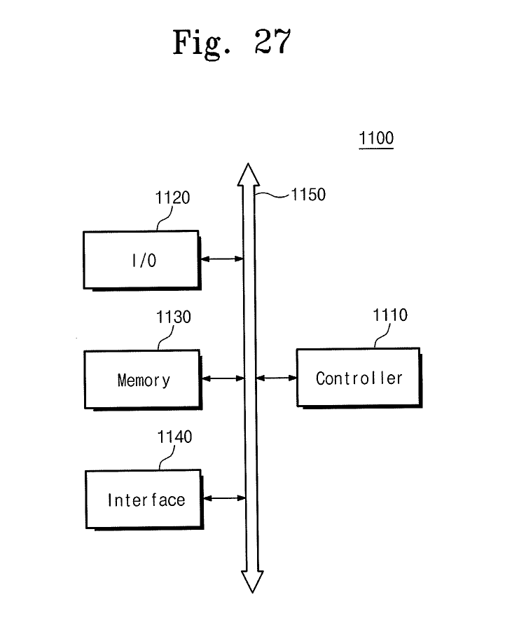

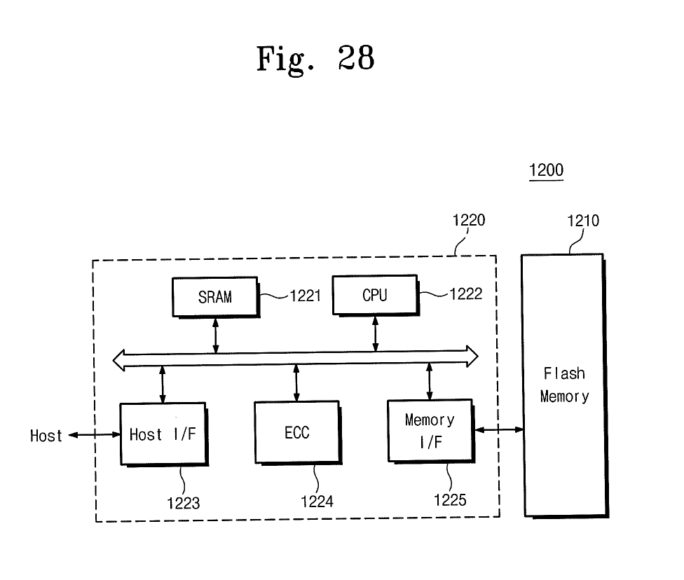

FIG. 27 is a schematic block diagram illustrating an example of a memory system, in which a vertical semiconductor device according to example embodiments of the inventive concept is provided.

Referring to FIG. 27, a memory system 1100 can be applied to, e.g., a personal digital assistant (PDA), a portable computer, a web tablet, a wireless phone, a mobile phone, a digital music player, a memory card and/or all the devices that can transmit and/or receive data in a wireless communication environment. The memory system 1100 may include a controller 1110, an input/output device 1120, e.g., such as a keypad and a display device, a memory 1130, an interface 1140, and a bus 1150. The memory 1130 and the interface 1140 communicate with each other through the bus 1150.

The controller 1110 may include at least one microprocessor, at least one digital signal processor, at least one micro controller or other process devices similar to the microprocessor, the digital signal processor, and the micro controller. The memory 1130 may be used to store an instruction executed by the controller 1110. The input/output device 1120 may receive data or a signal from the outside of the system 1100 or transmit data or a signal to the outside of the system 1100. For example, the input/output device 1120 may include a keyboard, a keypad and/or a displayer.

The memory 1130 includes at least one of the nonvolatile memory devices according to example embodiments of the inventive concepts. The memory 1130 may further include a different kind of memory, a volatile memory device capable of random access and various kinds of memories. The interface 1140 transmits data to a communication network or receives data from a communication network.

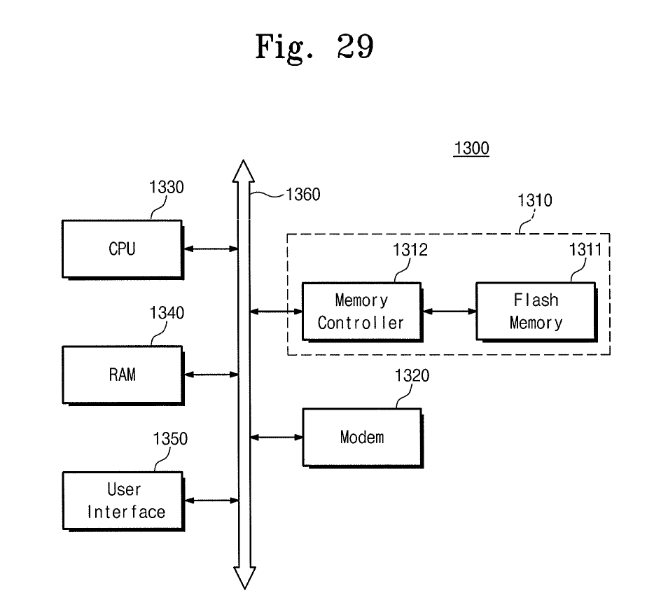

FIG. 28 is a schematic block diagram illustrating an example of a memory card, in which a vertical semiconductor device according to example embodiments of the inventive concept is provided.

Referring to FIG. 28, the memory card 1200 for supporting a storage capability of a large capacity is fitted with a semiconductor memory device 1210, which may be the nonvolatile memory devices according to example embodiments of the inventive concepts. The memory card 1200 includes a memory controller 1220 controlling every data exchange between a host and the semiconductor memory device 1210.

A static random access memory (SRAM) 1221 is used as an operation memory of a processing unit 1222. A host interface 1223 includes data exchange protocols of a host to be connected to the memory card 1200. An error correction block 1224 detects and corrects errors included in data readout from a multi bit semiconductor memory device 1210. A memory interface 1225 interfaces with the semiconductor memory device 1210. The processing unit 1222 performs every control operation for exchanging data of the memory controller 1220. Even though not depicted in drawings, it is apparent to one of ordinary skill in the art that the memory card 1200 according to example embodiments of the inventive concepts may further include a ROM ((not shown)) storing code data for interfacing with the host.

The semiconductor memory device 1210 according to the inventive concept may be used to realize a highly reliable memory card or other memory systems. In particular, the semiconductor memory device according to the inventive concept may constitute a memory system of the latest actively developed solid state drives (SSD).

FIG. 29 is a schematic block diagram illustrating an example of an information processing system, in which a vertical semiconductor device according to example embodiments of the inventive concept is provided.

Referring to FIG. 29, an information processing system 1300 may be realized using a memory system 1310 including at least one of the nonvolatile memory devices according to example embodiments of the inventive concepts. For instance, the information processing system 1300 may be a mobile device and/or a desktop computer. In some embodiments, the information processing system 1300 may further include a modem 1320, a central processing unit (CPU) 1330, a random access memory (RAM) 1340, and a user interface 1350, which are electrically connected to a system bus 1360, in addition to the memory system 1310. The memory system 1310 may include a memory device 1311 and a memory controller 1312. In some embodiments, the memory system 1310 may be configured substantially identical to the memory system 1100 or the memory card 1200. Data processed by the CPU 1330 and/or input from the outside may be stored in the memory system 1310. In some embodiments, the memory system 1310 may be used as a portion of a solid state drive (SSD), and in this case, the information processing system 1300 may stably and reliably store a large amount of data in the memory system 1310. Although not illustrated, it is apparent to those skilled in the art that, for example, an application chipset, a camera image sensor, a camera image signal processor (ISP), an input/output device, or the like may further be included in the information processing system 1300 according to the inventive concepts.

Furthermore, a nonvolatile memory device according to the inventive concept or a memory system including the same may be packaged in various kinds of ways. For instance, the nonvolatile memory device or the memory system may be employed in a Package on Package (PoP), Ball Grid Array (BGA), Chip Scale Package (CSP), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), or Wafer-level Processed Stack Package (WSP). The package in which the nonvolatile memory device according to one of the above embodiments is mounted may further include at least one semiconductor device (e.g., a controller and/or a logic device) that controls the nonvolatile memory device.

According to example embodiments of the inventive concepts, a nonvolatile memory device may include a memory gate pattern, in which an ohmic layer is not provided, and a non-memory gate pattern, in which an ohmic layer is provided. As the memory gate pattern may not include an ohmic layer with a crystallized structure, e.g., a metal silicide layer, a grain size of a metal pattern, e.g., a control gate electrode serving as a word line, may increase, thereby reducing line and sheet resistances of the word line and increasing data transfer speed in a cell array region. As the non-memory gate pattern in a peripheral circuit region, in contrast to the memory gate pattern in a cell region, may include a metal silicide layer serving as the ohmic layer between a polysilicon layer and a metal pattern, interfacial resistance between the polysilicon layer and the metal pattern may be reduced. As a result, an operating speed of transistors in the peripheral circuit region may increase. Accordingly, in nonvolatile memory devices according to example embodiments of the inventive concept, a signal transfer speed can be increased at both the cell array region and the peripheral circuit region.

In contrast, when a metal layer is formed on a metal silicide layer in a conventional memory gate pattern of a cell region having a polysilicon/metal gate structure, the metal layer may have a reduced grain size and this may lead to an increase in resistivity of the metal layer. As such, the sheet resistance of the word lines in the conventional semiconductor memory device may be increased.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A nonvolatile memory device, comprising:
a substrate;
a memory gate pattern on the substrate; and
a non-memory gate pattern on the substrate, the non-memory gate pattern being spaced apart from the memory gate pattern,
wherein the non-memory gate pattern includes an ohmic layer, and the memory gate pattern is provided without an ohmic layer.

2. The device as claimed in claim 1, wherein the ohmic layer is a metal silicide layer.

3. The device as claimed in claim 1, wherein the memory gate pattern includes a tunnel insulating layer, a data storing pattern, a first blocking insulating layer, and a control gate pattern sequentially.

4. The device as claimed in claim 3, wherein the data storing pattern is a floating gate pattern or a charge trap layer.

5. The device as claimed in claim 3, wherein the nonvolatile memory device is a NAND FLASH memory device, the control gate pattern serves as a word line of the NAND FLASH memory device, and the non-memory gate pattern serves as a gate pattern of at least one of a string selection transistor and a ground selection transistor.

6. The device as claimed in claim 3, wherein the control gate includes a first lower conductive pattern, a resistor pattern, a first diffusion barrier pattern, and a first upper conductive pattern sequentially stacked on the substrate, and the resistor pattern exhibits electric resistance higher than that of the ohmic layer.

7. The device as claimed in claim 6, wherein the resistor pattern includes a metal silicon nitride.

8. The device as claimed in claim 3, wherein the non-memory gate pattern includes a second lower conductive pattern, the ohmic layer, a second diffusion barrier pattern, and a second upper conductive pattern sequentially stacked on the substrate in the order stated, and the data storing pattern and the second lower conductive pattern are formed of the same polysilicon layer.

9. The device as claimed in claim 1, wherein:
the memory gate pattern includes a first lower conductive pattern, a first blocking insulating layer, a first intermediate conductive pattern, a first diffusion barrier pattern, and a first upper conductive pattern sequentially stacked on the substrate, and
the non-memory gate pattern includes a second lower conductive pattern, a second blocking insulating layer, a second intermediate conductive pattern, a second diffusion barrier pattern penetrating through the second intermediate conductive pattern and the second blocking insulating layer to be adjacent to the second lower conductive pattern, a second upper conductive pattern on the second diffusion barrier pattern, and the ohmic layer between the second diffusion barrier pattern and the second lower conductive pattern and between the second diffusion barrier pattern and the second intermediate conductive pattern.

10. The device as claimed in claim 9, wherein:
the ohmic layer covers a sidewall of the second intermediate conductive pattern and exposes a top surface of the second intermediate conductive pattern,
the memory gate pattern further comprises a first resistor pattern between the first diffusion barrier pattern and the first intermediate conductive pattern, and
the non-memory gate pattern further comprises a second resistor pattern between the second diffusion barrier pattern and a top surface of the second intermediate conductive pattern.

11. The device as claimed in claim 10, wherein the non-memory gate pattern further comprises a metal layer between the ohmic layer and the second diffusion barrier pattern.

12. The device as claimed in claim 1, further comprising an active pillar protruding from the substrate, the memory gate pattern being adjacent to a sidewall of the active pillar.

13. The device as claimed in claim 1, further comprising:
a semiconductor pattern spaced apart from the substrate in a vertical direction; and
an active pillar vertically protruding from the semiconductor pattern, the memory gate pattern being adjacent to a sidewall of the active pillar, and the non-memory gate pattern being below the semiconductor pattern.

14. The device as claimed in claim 1, wherein the substrate includes a cell array region and a peripheral circuit region, the memory gate pattern being in the cell array region, and the non-memory gate pattern being in the peripheral circuit region.

15. A semiconductor device, comprising:
a first insulating layer, a first conductive pattern, a second insulating layer, and a second conductive pattern sequentially stacked on a substrate in the stated order;
a diffusion barrier pattern penetrating the second conductive pattern and the second blocking insulating layer, the diffusion barrier pattern being adjacent to the first conductive pattern;
an ohmic layer interposed between a sidewall of the second conductive pattern and the diffusion barrier pattern and between the first conductive pattern and the diffusion barrier pattern; and
a resistor pattern interposed between a top surface of the second conductive pattern and the diffusion barrier pattern.

16. The device as claimed in claim 15, wherein the resistor pattern exhibits electrical resistance higher than that of the ohmic layer.

17. The device as claimed in claim 16, wherein the resistor pattern includes a metal silicon nitride.

18. The device as claimed in claim 15, wherein the second insulating layer has a sidewall protruding laterally from a sidewall of the resistor pattern.

19. The device as claimed in claim 15, further comprising a metal layer interposed between the ohmic layer and the diffusion barrier pattern.

20. A nonvolatile memory device, comprising:
a memory gate pattern on a substrate, the memory gate pattern including a gate electrode having no direct contact with an ohmic layer; and
a non-memory gate pattern on the substrate, the non-memory gate pattern including an ohmic layer and being spaced apart from the memory gate pattern.

21. The device as claimed in claim 20, wherein the gate electrode of the memory gate pattern includes metal, the metal having no direct contact with a metal silicide layer.

22. The device as claimed in claim 21, wherein the ohmic layer in the non-memory gate pattern is a metal silicide layer, the non-memory gate pattern being in a peripheral circuit region.

23-29. (canceled)
